(19) United States
(12) Patent Application Publication
(10) Pub. No.: US 2025/0169344 A1
(43) Pub. Date: May 22, 2025

(54) METHOD OF MANUFACTURING DISPLAY DEVICE AND ELECTRONIC DEVICE INCLUDING DISPLAY DEVICE MANUFACTURED USING THE METHOD

(71) Applicant: Samsung Display Co., LTD., Yongin-si (KR)

(72) Inventors: GUANGHAI JIN, Yongin-si (KR); JIWON JUNG, Yongin-si (KR)

(21) Appl. No.: 18/946,612

(22) Filed: Nov. 13, 2024

(30) Foreign Application Priority Data
Nov. 20, 2023 (KR) 10-2023-0161495

(51) Int. Cl. H10K 71/50; H10K 59/12; H10K 59/80; H10K 59/88

(52) U.S. Cl. CPC H10K 71/50; H10K 59/1201; H10K 59/873; H10K 59/88

(57) ABSTRACT

A method of manufacturing a display device includes forming a display panel above a mother substrate including a cell area, and a dummy area surrounding the cell area, such that the display panel overlaps the cell area, forming cutouts by removing a portion of an edge of a protection film having a shape corresponding to a shape of the mother substrate, aligning the mother substrate and the protection film so that the dummy area corresponds to the cutouts, attaching the protection film to the mother substrate, removing the dummy area by cutting the mother substrate, and forming a display cell.

### CROSS-REFERENCE TO RELATED APPLICATION

This application claims priority to, and the benefit of, Korean Patent Application No. 10-2023-0161495, filed on Nov. 20, 2023, in the Korean Intellectual Property Office, the entire disclosure of which is incorporated herein by reference.

### BACKGROUND

### 1. Field

The present disclosure relates generally to a method of manufacturing a display device with reduced process dispersion and an electronic device including a display device manufactured using the method.

### 2. Description of the Related Art

With the development of information technology, the importance of a display device, which is a connection medium between a user and information, has been highlighted. For example, the use of display devices, such as liquid crystal display (LCD) device, organic light-emitting display (OLED) device, plasma display panel (PDP) device, quantum dot display device, or the like, is increasing.

Recently, a head-mounted display (HMD) including a display device has been developed. A head-mounted display is a glasses-type monitor device of virtual reality (VR) or augmented reality (AR) that is worn in the form of glasses, helmets, etc. to create a focal point in close proximity to the user's eyes. A head-mounted display may provide an image displayed on a display device to the user's eyes through a lens. High-resolution micro OLED may be applied to the head-mounted display. High-resolution micro OLED may be an organic light-emitting diode on silicon (OLEDoS) formed using a silicon wafer-based semiconductor process.

### SUMMARY

Embodiments provide a method of manufacturing a display device with improved alignment accuracy between a mother substrate and a protection film.

Embodiments provide an electronic device including a display device manufactured using the method.

A method of manufacturing a display device according to one or more embodiments of the present disclosure includes forming a display panel above a mother substrate including a cell area, and a dummy area surrounding the cell area, such that the display panel overlaps the cell area, forming cutouts by removing a portion of an edge of a protection film having a shape corresponding to a shape of the mother substrate, aligning the mother substrate and the protection film so that the dummy area corresponds to the cutouts, attaching the protection film to the mother substrate, removing the dummy area by cutting the mother substrate, and forming a display cell.

The protection film may include a carrier film having the cutouts at an edge of the carrier film, and panel protection films on the carrier film and spaced apart from each other.

The attaching the protection film to the mother substrate may include overlapping the dummy area and the cutouts so that one of the panel protection films overlaps the display panel, and removing the carrier film.

The method may further include removing the panel protection films.

The cutouts may be respectively defined by a first cutting line extending in a first direction, and a second cutting line extending in a second direction crossing the first direction.

The first cutting line may be substantially perpendicular to the second cutting line.

The cutouts may be point symmetrical with respect to a center of the protection film.

The method may further include forming a polarization layer above the display panel.

The forming the display panel may include forming a light-emitting element layer above the mother substrate in the cell area, and forming an encapsulation layer above the light-emitting element layer.

The forming the display panel may further include forming a lens layer including micro lenses above the encapsulation layer, and forming an encapsulation substrate above the lens layer.

The mother substrate may include a silicon wafer.

A method of manufacturing a display device according to one or more other embodiments of the present disclosure includes forming a display panel above a mother substrate including a cell area and a dummy area surrounding the cell area, such that the display panel overlaps the cell area, forming a protection film including a main portion having a shape corresponding to a shape of the mother substrate, and protrusions protruding from an edge of the main portion, aligning the mother substrate and the protection film so that the dummy area corresponds to the protrusions, attaching the protection film to the mother substrate, removing the dummy area by cutting the mother substrate, and forming a display cell.

The protection film may include a carrier film including the main portion and the protrusions, and panel protection films on the carrier film and spaced apart from each other.

The attaching the protection film to the mother substrate may include overlapping the dummy area and the protrusions so that one of the panel protection films overlaps the display panel, and removing the carrier film.

The method may further include removing the panel protection films.

The protrusions may have a polygonal planar shape.

The protrusions may be point symmetrical with respect to a center of the main portion.

The forming the display panel may include forming a light-emitting element layer above the mother substrate in the cell area, forming an encapsulation layer above the light-emitting element layer, forming a lens layer including micro lenses above the encapsulation layer, and forming an encapsulation substrate above the lens layer.

The mother substrate may include a silicon wafer.

An electronic device according to one or more other embodiments of the present disclosure includes a display device manufactured using the method described above and a power supply configured to provide power to the display device.

A method of manufacturing a display device according to one or more embodiments of the present disclosure may include forming a plurality of cutouts by removing a portion of an edge of a protection film, the protection film having a shape corresponding to a shape of a mother substrate, aligning the mother substrate and the protection film so that a dummy area of the mother substrate and the plurality of cutouts correspond, and attaching the protection film to the mother substrate.

In a process of forming the plurality of cutouts at the edge of the protection film, process dispersion may be reduced compared to a process of forming separate align marks on the protection film. Accordingly, the alignment accuracy between the protection film and the mother substrate may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is an enlarged plan view of area ‘A’ of FIG. 1.

FIG. 3 is a cross-sectional view taken along the line I-I′ of FIG. 2.

FIG. 4 is a cross-sectional view illustrating the display device of FIG. 1.

FIG. 5 is a flowchart illustrating a method of manufacturing a display device according to one or more embodiments of the present disclosure.

FIGS. 6, 7, 8, and 9 are views illustrating the method of manufacturing the display device of FIG. 5.

FIG. 10 is a flowchart corresponding to the method of manufacturing the display device of FIG. 5.

FIGS. 11, 12, 13, 14, 15, 16, 17, and 18 are views illustrating the method of manufacturing the display device of FIG. 5.

FIG. 19 is a flowchart illustrating a method of manufacturing a display device according to one or more other embodiments of the present disclosure.

FIGS. 20 and 21 are views illustrating the method of manufacturing the display device of FIG. 19.

FIG. 22 is a flowchart corresponding to the method of manufacturing the display device of FIG. 19.

FIGS. 23 and 24 are views illustrating the method of manufacturing the display device of FIG. 19.

FIG. 25 is a block diagram illustrating an electronic device according to one or more other embodiments of the present disclosure.

FIG. 26 is a view illustrating an example in which the electronic device of FIG. 25 is implemented as a head mounted display device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

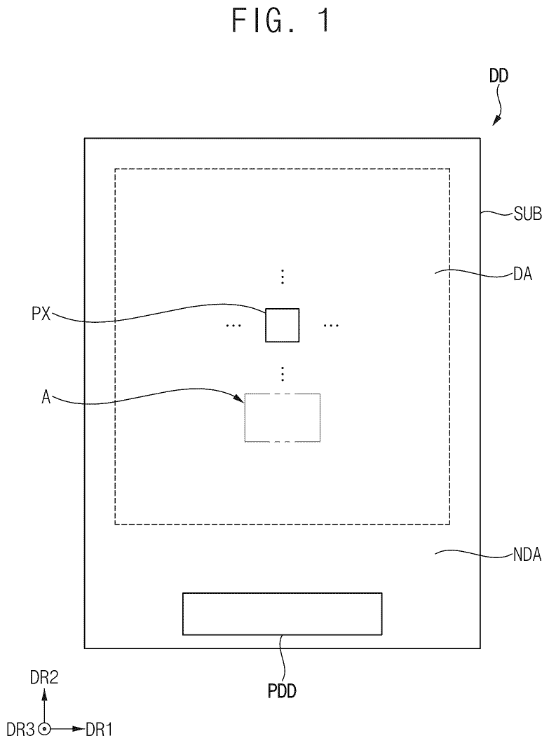

FIG. 1 is a plan view illustrating a display device according to one or more embodiments of the present disclosure.

In this specification, a plane may be defined by a first direction DR1, and by a second direction DR2 crossing the first direction DR1. For example, the first direction DR1 and the second direction DR2 may be perpendicular to each other. A direction normal to the plane, that is, a thickness direction of a display device DD, may be a third direction DR3. In other words, the third direction DR3 may be perpendicular to each of the first direction DR1 and the second direction DR2.

Referring to FIG. 1, the display device DD according to one or more embodiments of the present disclosure may include a substrate SUB and a pad portion PDD.

The substrate SUB may include a display area DA and a non-display area NDA. The display area DA may be defined as an area which displays an image by generating light or adjusting the transmittance of light provided from an external light source. A plurality of pixels PX may be arranged in the display area DA. Each of the pixels PX may generate light according to a driving signal. For example, the pixels PX may be arranged in a matrix form along the first direction DR1 and the second direction DR2.

Signal lines, such as gate lines and data lines, may be located in the display area DA. Each of the pixels PX may be connected to the signal lines. Each of the pixels PX may receive a gate signal, a data signal, etc. from the signal lines. Accordingly, an image may be displayed in the display area DA in the third direction DR3. The display area DA may have a rectangular planar shape. However, the planar shape of the display area DA is not limited thereto, and the display area DA may have various planar shapes, such as circular, ellipse, and polygonal shapes.

The non-display area NDA may be defined as an area that does not display an image. The non-display area NDA may be positioned around the display area DA (e.g., in plan view). For example, the non-display area NDA may entirely surround the display area DA. Drivers for driving the pixels PX may be located in the non-display area NDA.

The pad portion PDD may be located on the substrate SUB in the non-display area NDA. The pad portion PDD may be located in the non-display area NDA positioned on one side of the display area DA. For example, the pad portion PDD may be located in the non-display area NDA positioned below the display area DA. The pad portion PDD may include a plurality of pads, and the plurality of pads may be connected to a printed circuit board through an anisotropic conductive film.

The display device DD according to one or more embodiments of the present disclosure may be a display device that displays an image. For example, the display device DD may be a display device, such as an organic light-emitting diode display device, a liquid crystal display device, an organic light-emitting diode on silicon (OLEDoS), a liquid crystal on silicon (LCoS), or a light-emitting diode on silicon (LEDoS).

In one or more embodiments, the display device DD may be a display device, such as an organic light-emitting diode on silicon (OLEDoS). When the display device DD is a display device, such as OLEDoS, the display device DD may configure a head-mounted display, which is a glasses-type monitor device of virtual reality or augmented reality that is worn in the form of glasses, helmets, etc. to create a focal point in close proximity to the user's eyes. However, the present disclosure is not limited thereto, and the display device DD may configure various displays.

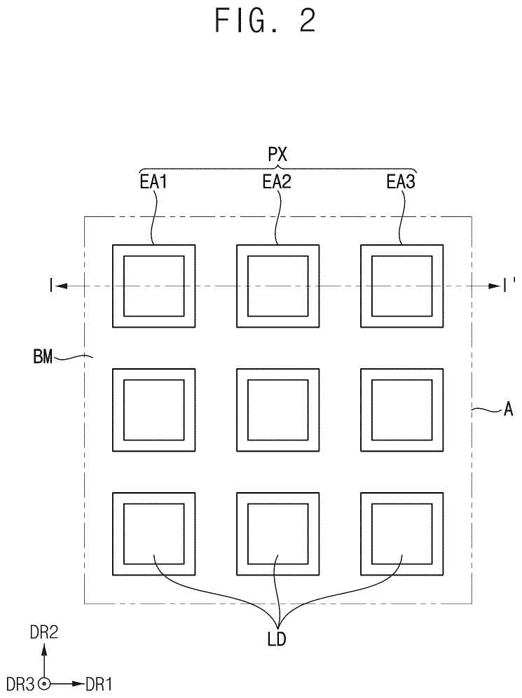

FIG. 2 is an enlarged plan view of area ‘A’ of FIG. 1.

Referring to FIG. 2, each of the pixels PX may include a first light-emitting area EA1, a second light-emitting area EA2, and a third light-emitting area EA3, which emit light. In FIG. 2, each of the pixels PX is illustrated as including three light-emitting areas EA1, EA2, and EA3, but the present disclosure is not limited thereto. For example, each of the pixels PX may include four or more light-emitting areas.

For example, each of the first light-emitting area EA1, the second light-emitting area EA2, and the third light-emitting area EA3 may have a triangular planar shape, a rectangular planar shape, a circular planar shape, a track-shaped planar shape, an ellipse planar shape, etc. In one or more embodiments, each of the first light-emitting area EA1, the second light-emitting area EA2, and the third light-emitting area EA3 may have a rectangular planar shape. However, the present disclosure is not limited thereto, and each of the first light-emitting area EA1, the second light-emitting area EA2, and the third light-emitting area EA3 may have a different planar shape. For example, each of the first light-emitting area EA1, the second light-emitting area EA2, and the third light-emitting area EA3 may have a different respective size and/or shape, or may have the same size and/or shape.

Each of the first light-emitting area EA1, the second light-emitting area EA2, and the third light-emitting area EA3 may include a light-emitting element LD, which emits first light. For example, the first light may be white light. However, the present disclosure is not limited to this, and the light-emitting element LD included in the first light-emitting area EA1 may emit red light, the light-emitting element LD included in the second light-emitting area EA2 may emit green light, and the light-emitting element LD included in the third light-emitting area EA3 may emit blue light.

The first light-emitting area EA1 may emit second light. The first light-emitting area EA1 may convert the first light emitted from the light-emitting element LD into the second light, and may emit the second light. For example, the second light may be red light, but the present disclosure is not limited thereto.

The second light-emitting area EA2 may emit third light. The second light-emitting area EA2 may convert the first light emitted from the light-emitting element LD into the third light, and may emit the third light. For example, the third light may be green light, but the present disclosure is not limited thereto.

The third light-emitting area EA3 may emit fourth light. The third light-emitting area EA3 may convert the first light emitted from the light-emitting element LD into the fourth light, and may emit the fourth light. For example, the fourth light may be blue light, but the present disclosure is not limited thereto.

The first light-emitting area EA1, the second light-emitting area EA2, and the third light-emitting area EA3 may be arranged along the first direction DR1. For example, the first light-emitting area EA1, the second light-emitting area EA2, and the third light-emitting area EA3 may be sequentially arranged along the first direction DR1. In addition, the first light-emitting area EA1, the second light-emitting area EA2, and the third light-emitting area EA3 may be arranged along the second direction DR2. However, the present disclosure is not limited thereto.

The first light-emitting area EA1, the second light-emitting area EA2, and the third light-emitting area EA3 may be defined by a light-blocking portion BM. The light-blocking portion BM may surround each of the first light-emitting area EA1, the second light-emitting area EA2, and the third light-emitting area EA3. For example, the light-blocking portion BM may have a mesh shape, a net shape, a lattice shape, etc. in a plan view.

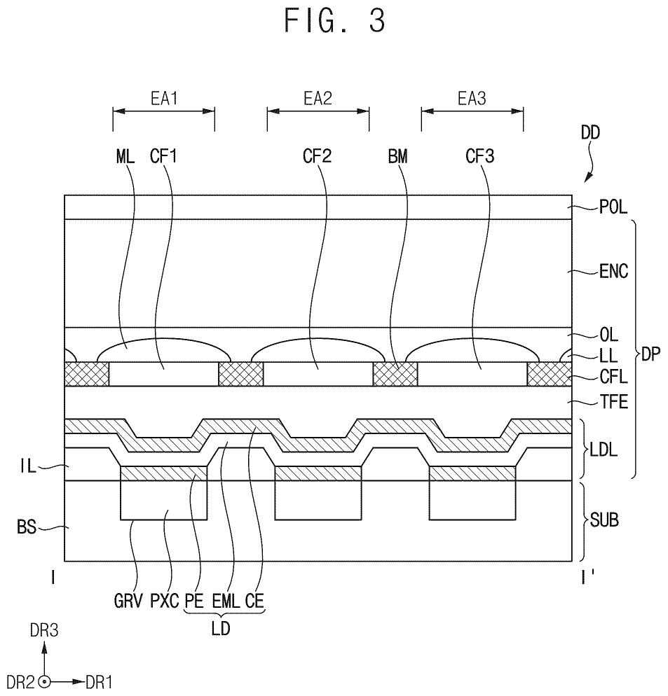

FIG. 3 is a cross-sectional view taken along the line I-I′ of FIG. 2.

Referring to FIG. 3, the display device DD according to one or more embodiments of the present disclosure may include the substrate SUB, a display panel DP, and a polarization layer POL. The display panel DP may include a light-emitting element layer LDL, an encapsulation layer TFE, a color filter layer CFL, a lens layer LL, a filling layer OL, and an encapsulation substrate ENC.

The substrate SUB may include a base substrate BS and a plurality of pixel circuit portions PXC. In one or more embodiments, the substrate SUB may be a semiconductor circuit board. The substrate SUB may include a silicon wafer.

The base substrate BS may define a plurality of grooves GRV. The pixel circuit portions PXC may be accommodated in the plurality of grooves GRV, respectively. Each of the pixel circuit portions PXC may include at least one transistor. In addition, each of the pixel circuit portions PXC may further include at least one capacitor.

The display panel DP may be located on the substrate SUB (as used herein, “located on” may mean “above”). For example, the light-emitting element layer LDL may be located on the substrate SUB. The light-emitting element layer LDL may include a plurality of light-emitting elements LD and an insulating layer IL. Each of the light-emitting elements LD may include a pixel electrode PE, a light-emitting layer EML, and a common electrode CE.

The insulating layer IL may be located on the substrate SUB. The insulating layer IL may define openings that expose the pixel circuit portions PXC. The insulating layer IL may include an inorganic insulating material and/or an organic insulating material. Examples of the inorganic insulating material that may be used as the insulating layer IL may include silicon oxide (SiOₓ), silicon nitride (SiNₓ), silicon oxynitride (SiOₓN_{y}), etc. These may be used alone or in combination with each other. Examples of the organic insulating material that may be used as the insulating layer IL may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be located in each of the first to third light-emitting areas EA1, EA2, and EA3 on the pixel circuit portions PXC. In other words, the pixel electrode PE may be located in the opening defined by the insulating layer IL. The pixel electrode PE may be connected to the pixel circuit portion PXC. Accordingly, the pixel electrode PE may receive voltage from the pixel circuit portion PXC. The pixel electrode PE may include a metal, an alloy, a metal nitride, a conductive metal oxide, a transparent conductive material, etc. Examples of materials that may be used as the pixel electrodes PE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other. For example, the pixel electrode PE may serve as an anode electrode.

The light-emitting layer EML may be located on the pixel electrode PE and the insulating layer IL. In addition, the light-emitting layer EML may extend along the first to third light-emitting areas EA1, EA2, and EA3. However, the present disclosure is not limited thereto, and the light-emitting layer EML may be independently located in each of the first to third light-emitting areas EA1, EA2, and EA3. The light-emitting layer EML may include an organic material that emits light of a corresponding color. In one or more embodiments, the light-emitting layer EML may include an organic light-emitting material that emits white light.

The common electrode CE may be located on the light-emitting layer EML. The common electrode CE may extend along the first to third light-emitting areas EA1, EA2, and EA3. The common electrode CE may include a metal, an alloy, a metal nitride, a conductive metal oxide, a transparent conductive material, etc. These may be used alone or in combination with each other. For example, the common electrode CE may serve as a cathode electrode.

Accordingly, the light-emitting elements LD each including the pixel electrode PE, the light-emitting layer EML, and the common electrode CE may be located on the substrate SUB.

The encapsulation layer TFE may be located on the light-emitting element layer LDL. The encapsulation layer TFE may prevent impurities, moisture, etc. from penetrating into the light-emitting element layer LDL from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer, such as polyacrylate.

The encapsulation layer TFE may have a structure in which the inorganic encapsulation layer and the organic encapsulation layer are alternately stacked. For example, the encapsulation layer TFE may have a three-layer structure in which two inorganic encapsulation layers and one organic encapsulation layer are alternately stacked. However, the present disclosure is not limited to thereto, and the encapsulation layer TFE may have a five-layer structure in which three inorganic encapsulation layers and two organic encapsulation layers are alternately stacked, or may have a seven-layer structure in which four inorganic encapsulation layers and three organic encapsulation layers are alternately stacked.

The color filter layer CFL may be located on the encapsulation layer TFE. The color filter layer CFL may include the light-blocking portion BM, a first color filter CF1, a second color filter CF2, and a third color filter CF3.

The light-blocking portion BM may be located on the encapsulation layer TFE. The light-blocking portion BM may partition the first light-emitting area EA1, the second light-emitting area EA2, and the third light-emitting area EA3. In other words, the light-blocking portion BM may define a plurality of openings dividing the first to third light-emitting areas EA1, EA2, and EA3. Accordingly, the light-blocking portion BM may not overlap the first to third light-emitting areas EA1, EA2, and EA3. The light-blocking portion BM may include an inorganic material and/or an organic material that has a black color. For example, the light-blocking portion BM may include black pigment, black dye, carbon black, etc. These may be used alone or in combination with each other.

The first color filter CF1, the second color filter CF2, and the third color filter CF3 may be located within the openings defined by the light-blocking portion BM, respectively.

The first color filter CF1 may be located on the encapsulation layer TFE in the first light-emitting area EA1. The first color filter CF1 may transmit the second light among the first light emitted from the light-emitting element layer LDL, and may absorb or block the third light and the fourth light. For example, the first color filter CF1 may transmit red light, and may absorb or block green light and blue light. However, the present disclosure is not limited thereto.

The second color filter CF2 may be located on the encapsulation layer TFE in the second light-emitting area EA2. The second color filter CF2 may transmit the third light among the first light emitted from the light-emitting element layer LDL, and may absorb or block the second light and the fourth light. For example, the second color filter CF2 may transmit green light, and may absorb or block red light and blue light. However, the present disclosure is not limited thereto.

The third color filter CF3 may be located on the encapsulation layer TFE in the third light-emitting area EA3. The third color filter CF3 may transmit the fourth light among the first light emitted from the light-emitting element layer LDL, and may absorb or block the second light and the third light. For example, the third color filter CF3 may transmit blue light, and may absorb or block red light and green light. However, the present disclosure is not limited thereto.

The lens layer LL may be located on the color filter layer CFL. The lens layer LL may include a plurality of micro lenses ML. The micro lenses ML may be located on the first to third color filters CF1, CF2, and CF3, respectively. The micro lenses ML may have a refractive index (e.g., predetermined refractive index). The micro lenses ML may improve light extraction efficiency.

The filling layer OL may be located on the lens layer LL. The filling layer OL may flatten an upper surface of the color filter layer CFL and an upper surface of the lens layer LL. The filling layer OL may include an inorganic insulating material and/or an organic insulating material. Examples of the inorganic insulating material that may be used as the filling layer OL may include silicon oxide (SiOₓ), silicon nitride (SiNₓ), silicon oxynitride (SiOₓN_{y}), etc. These may be used alone or in combination with each other. Examples of the organic insulating material that may be used as the filling layer OL may include an acrylic polymer, an imide polymer, an amide polymer, a fluorine polymer, an aryl ether polymer, a vinyl alcohol polymer, etc. These may be used alone or in combination with each other.

The encapsulation substrate ENC may be located on the filling layer OL. The encapsulation substrate ENC may be attached to one surface of the filling layer OL through an adhesive member. The encapsulation substrate ENC may include a transparent material. For example, the encapsulation substrate ENC may include glass or plastic.

The polarization layer POL may be located on the encapsulation substrate ENC. The polarization layer POL may reduce external light reflection of the display device DD. As external light reflection is reduced, visibility of the display device DD may be improved. Alternatively, the polarization layer POL may be omitted.

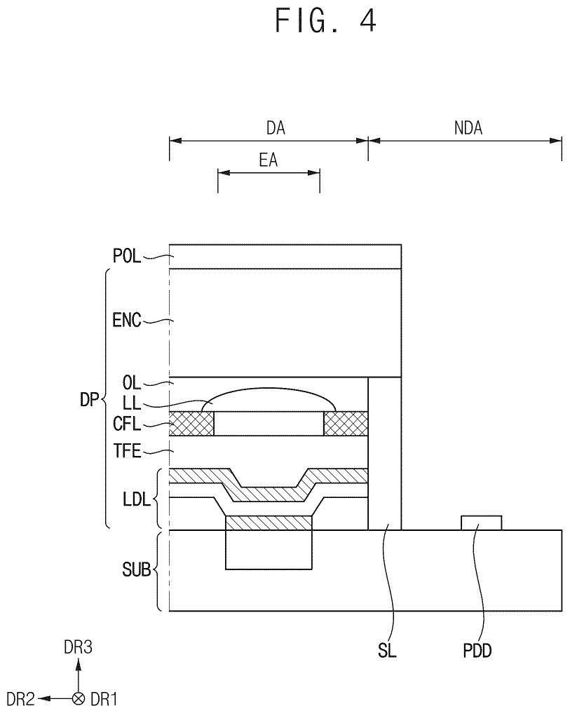

FIG. 4 is a cross-sectional view illustrating the display device of FIG. 1.

Referring to FIG. 4, the display device DD according to one or more embodiments of the present disclosure may include the substrate SUB, the display panel DP, the polarization layer POL, a sealing member SL, and the pad portion PDD. The display panel DP may include the light-emitting element layer LDL, the encapsulation layer TFE, the color filter layer CFL, the lens layer LL, the filling layer OL, and the encapsulation substrate ENC.

The sealing member SL may be located on the substrate SUB in the non-display area NDA. The sealing member SL may cover a side surface of the light-emitting element layer LDL. For example, the sealing member SL may cover a side surface of each of the light-emitting layer LDL, the encapsulation layer TFE, the color filter layer CFL, and the filling layer OL. The sealing member SL may include an inorganic material. For example, the sealing member SL may be a glass frit. The glass frit may include a main material, such as glass raw material in powder form, silicon oxide (SiOₓ), etc. In addition, the sealing member SL may be in a paste state including the silicon oxide, a laser absorber or infrared absorber, an organic binder, and a filler to reduce the thermal expansion coefficient. When a laser is irradiated to the sealing member SL, the sealing member SL may be melted and cured.

The encapsulation substrate ENC may be located on the filling layer OL and the sealing member SL. The encapsulation substrate ENC may entirely overlap the display area DA, and may partially overlap the non-display area NDA.

The polarization layer POL may be located on the encapsulation substrate ENC. The polarization layer POL may entirely overlap the encapsulation substrate ENC. In addition, the polarization layer POL may entirely overlap the display area DA and partially overlap the non-display area NDA.

The pad portion PDD may be located on the substrate SUB in the non-display area NDA. The pad portion PDD may be located in the non-display area NDA positioned on one side of the display area DA. The pad portion PDD may be spaced apart from the display panel DP.

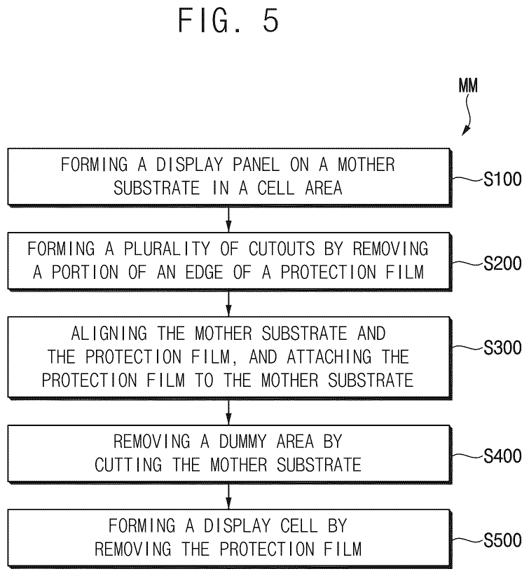

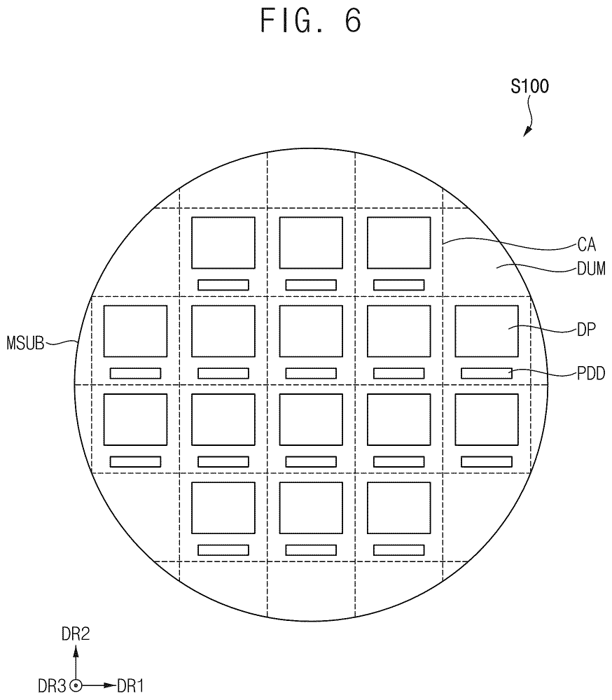

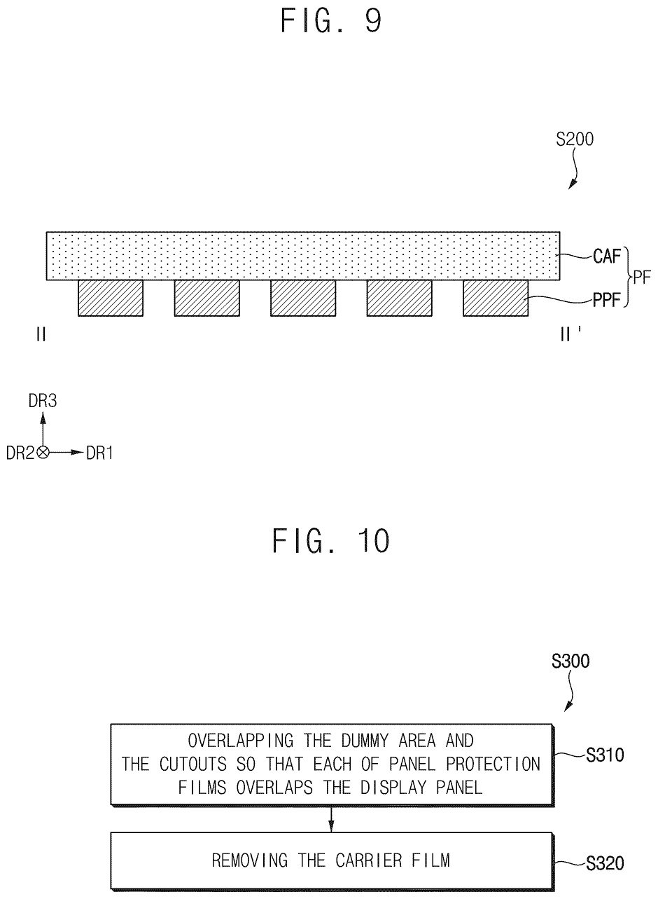

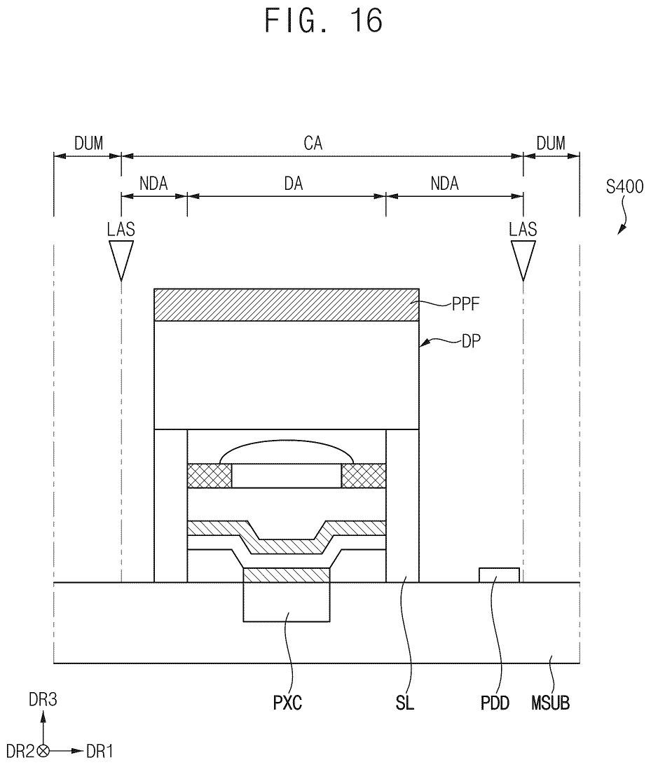

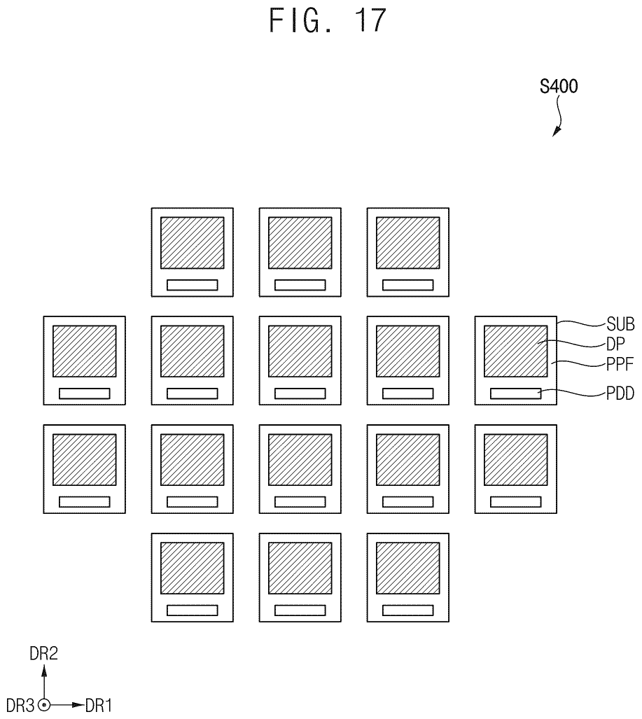

FIG. 5 is a flowchart illustrating a method of manufacturing a display device according to one or more embodiments of the present disclosure. FIGS. 6, 7, 8, 9, 11, 12, 13, 14, 15, 16, 17, and 18 are views illustrating the method of manufacturing the display device of FIG. 5. FIG. 10 is a flowchart corresponding to the method of manufacturing the display device of FIG. 5.

Referring to FIG. 5, a method MM of manufacturing a display device according to one or more embodiments of the present disclosure may include forming a display panel on a mother substrate in a cell area (S100), forming a plurality of cutouts by removing a portion of an edge of a protection film (S200), aligning the mother substrate and the protection film, and attaching the protection film to the mother substrate (S300), removing a dummy area by cutting the mother substrate (S400), and forming a display cell by removing the protection film (S500).

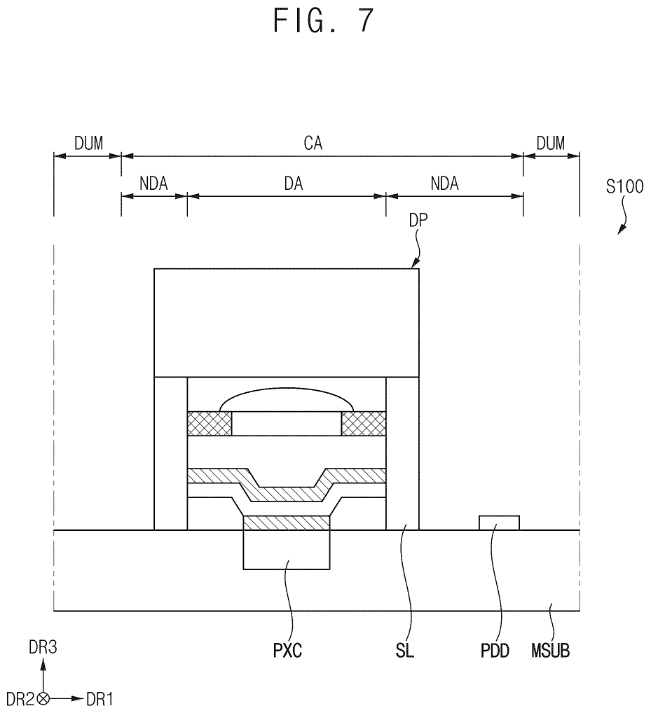

Referring to FIGS. 6 and 7, a display panel DP may be formed on a mother substrate MSUB in a cell area CA (S100).

The mother substrate MSUB may be formed of a silicon wafer. In addition, a plurality of pixel circuit portions PXC may be formed on the mother substrate MSUB. The mother substrate MSUB may include a plurality of substrates (e.g., the substrate SUB of FIG. 3). In a subsequent process, the plurality of substrates may be formed by cutting the mother substrate MSUB.

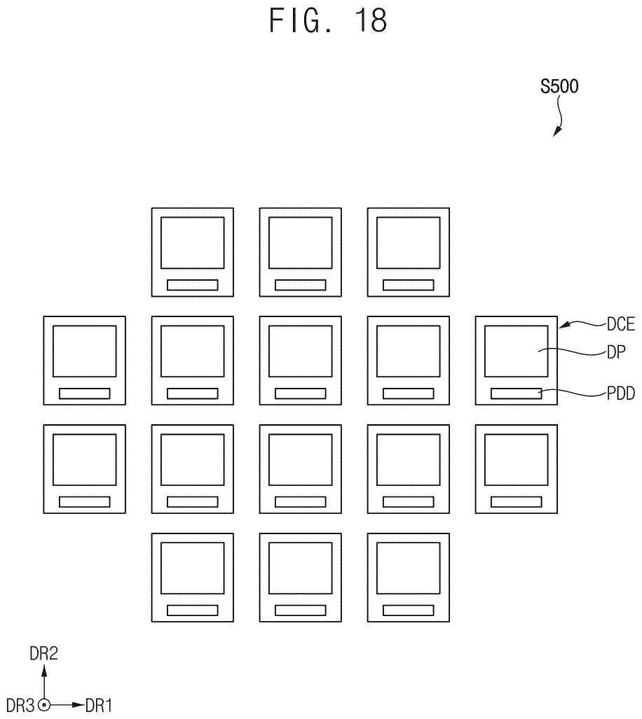

The mother substrate MSUB may include the cell area CA and a dummy area DUM. The cell area CA may be defined as an area where a display cell (e.g., a display cell DCE of FIG. 18) is formed. The cell area CA may include the display area DA and the non-display area NDA. The display area DA may be defined as an area that displays an image in the display cell. The non-display area NDA may be defined as an area that does not display an image in the display cell.

The dummy area DUM may be positioned around the cell area CA. For example, the dummy area DUM may entirely surround the cell area CA. The dummy area DUM may be defined as an area to be removed in a subsequent process.

The display panel DP, a sealing member SL, and a pad portion PDD may be formed on the mother substrate MSUB in the cell area CA.

The light-emitting element layer LDL, which is illustrated in FIG. 3, may be formed on the mother substrate MSUB in the display area DA. The encapsulation layer TFE, the color filter layer CFL, the lens layer LL, and the filling layer OL, which are illustrated in FIG. 3, may be formed sequentially on the light-emitting element layer.

The sealing member SL may be formed on the mother substrate MSUB in the non-display area NDA. The sealing member SL may be formed to cover a side surface of each of the light-emitting element layer, the encapsulation layer, the color filter layer, and the filling layer.

The encapsulation substrate (e.g., the encapsulation substrate ENC of FIG. 3) may be formed on the filling layer and the sealing member SL. The encapsulation substrate may entirely overlap the display area DA, and may partially overlap the non-display area NDA.

Accordingly, the display panel DP including the light-emitting element layer, the encapsulation layer, the color filter layer, the lens layer, the filling layer, and the encapsulation substrate may be formed. The display panel DP may overlap the cell area CA. For example, the display panel DP may entirely overlap the display area DA, and may partially overlap the non-display area NDA.

The pad portion PDD may be formed on the mother substrate MSUB in the non-display area NDA. The pad portion PDD may be spaced apart from the display panel DP.

As illustrated in FIG. 6, sixteen display panels DP and sixteen pad portions PDD may be formed on the mother substrate MSUB, but the present disclosure is not limited thereto. For example, fewer than sixteen display panels DP and fewer than sixteen pad portions PDD may be formed on the mother substrate MSUB. For example, more than sixteen display panels DP and more than sixteen pad portions PDD may be formed on the mother substrate MSUB.

As illustrated in FIG. 6, the mother substrate MSUB may have a circular planar shape, but the present disclosure is not limited thereto. For example, the mother substrate MSUB may have an ellipse planar shape or a polygonal planar shape.

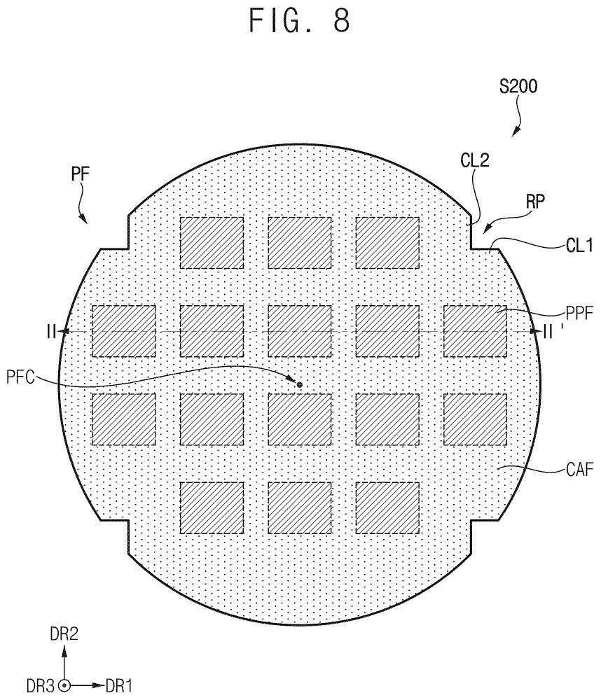

Referring to FIGS. 8 and 9, a plurality of cutouts RP may be formed by removing a portion of an edge of a protection film PF (S200).

The protection film PF may include a carrier film CAF, and panel protection films PPF located on one surface of the carrier film CAF.

The carrier film CAF may have a shape which corresponds to a shape of the mother substrate MSUB. For example, when the mother substrate MSUB has a circular planar shape, the carrier film CAF may have a circular planar shape. However, the present disclosure is not limited thereto. For another example, when the mother substrate MSUB has an ellipse planar shape, the carrier film CAF may have an ellipse planar shape.

A plurality of cutouts RP may be formed at an edge of the carrier film CAF. In one or more embodiments, the cutouts RP may be point symmetrical to each other with respect to a center PFC of the protection film PF. For example, the cutouts RP may be point symmetrical to each other with respect to a center of the carrier film CAF. For example, four cutouts RP, which are point symmetrical to each other with respect to the center of the carrier film CAF, may be formed at the edge of the carrier film CAF. However, the present disclosure is not limited thereto, and two or six cutouts RP, which are point symmetrical to each other with respect to the center of the carrier film CAF, may be formed at the edge of the carrier film CAF.

Each of the cutouts RP may be defined by a first cutting line CL1 extending in the first direction DR1, and a second cutting line CL2 extending in the second direction DR2. In one or more embodiments, as illustrated in FIG. 8, the first cutting line CL1 may be perpendicular to the second cutting line CL2. In other words, the first cutting line CL1 and the second cutting line CL2 may form a right angle. However, the present disclosure is not limited thereto. In one or more other embodiments, the first cutting line CL1 and the second cutting line CL2 may form an acute angle or an obtuse angle.

The panel protection films PPF may be located on the one surface of the carrier film CAF. The panel protection films PPF may be spaced apart from each other. Each of the panel protection films PPF may have a shape that corresponds to a shape of the display panel DP. For example, when the display panel DP has a rectangular planar shape, each of the panel protection films PPF may have a rectangular planar shape. In addition, each of the panel protection films PPF may have an area (or, size) corresponding to an area of the display panel DP.

A shape in which the panel protection films PPF are arranged on the carrier film CAF may correspond to a shape in which the display panels DP are arranged on the mother substrate MSUB. That is, a distance between the panel protection films PPF on the carrier film CAF may be the same as a distance between the display panels DP on the mother substrate MSUB. For example, if sixteen display panels DP are formed on the mother substrate MSUB, sixteen panel protection films PPF may be located on the carrier film CAF.

Referring to FIGS. 10, 11, 12, 13, and 14, the aligning the mother substrate MSUB and the protection film PF, and the attaching the protection film PF to the mother substrate MSUB (S300) may include overlapping the dummy area DUM and the cutouts RP so that each of the panel protection films PPF overlaps the display panel DP (S310), and removing the carrier film CAF (S320).

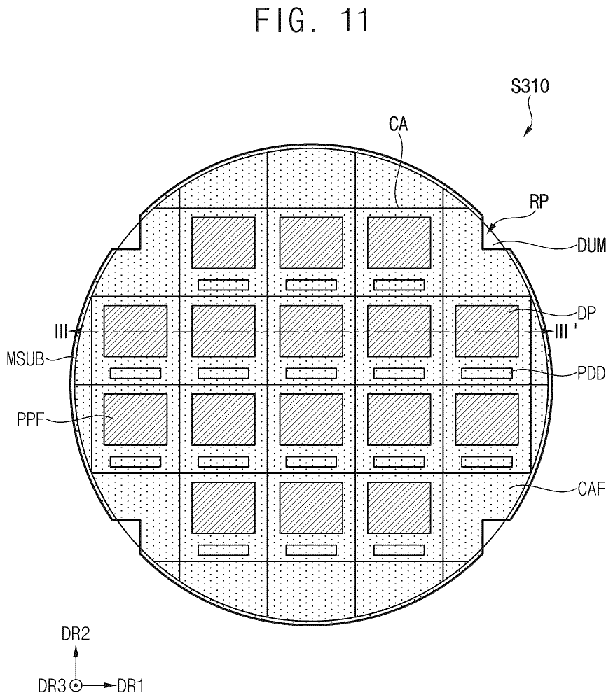

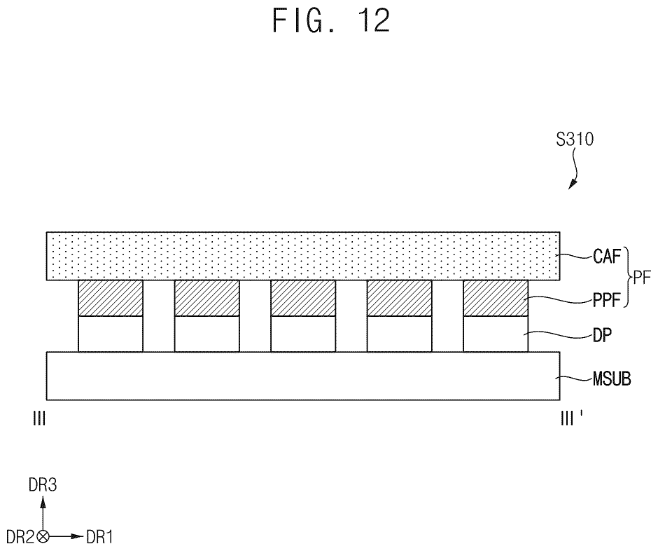

As illustrated in FIGS. 11 and 12, the dummy area DUM and the cutouts RP may overlap so that each of the panel protection films PPF overlaps the display panel DP (S310).

The mother substrate MSUB and the protection film PF may be aligned with each other. For example, the dummy area DUM of the mother substrate MSUB, and the cutouts RP formed at the edge of the carrier film CAF, may be aligned with each other. In a process of forming the cutouts RP at the edge of the carrier film CAF, process dispersion may be reduced compared to a process of forming separate align marks on the carrier film CAF. Accordingly, the alignment accuracy between the carrier film CAF and the mother substrate MSUB may be improved. When the mother substrate MSUB and the carrier film CAF are aligned so that the dummy area DUM and the cutouts RP correspond, each of the panel protection films PPF may overlap the display panel DP in a plan view.

After aligning the mother substrate MSUB and the carrier film CAF so that the dummy area DUM and the cutouts RP correspond, the protection film PF may be attached to the mother substrate MSUB. In this case, each of the panel protection films PPF may overlap the display panel DP, and the cutouts RP may overlap the dummy area DUM. In other words, each of the panel protection films PPF may directly contact the display panel DP. In addition, the edge of the carrier film CAF where the cutouts RP are formed may directly contact the dummy area DUM of the mother substrate SUB.

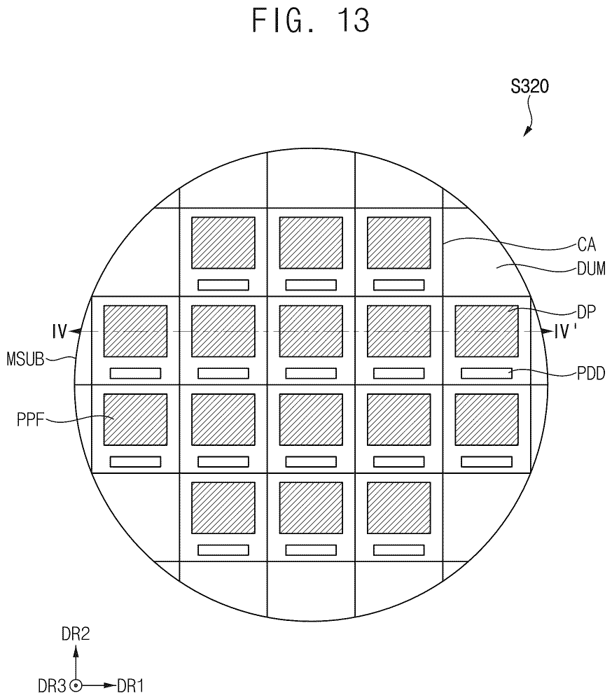

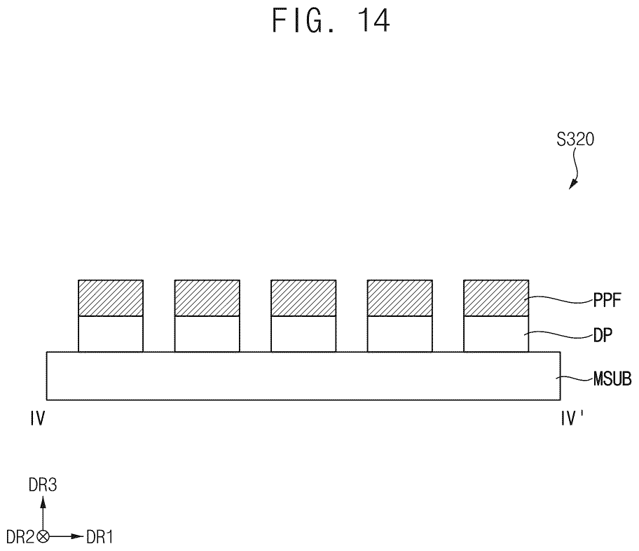

As illustrated in FIGS. 13 and 14, the carrier film CAF may be removed (S320).

After the carrier film CAF is aligned with the mother substrate MSUB, and after the panel protection films PPF are attached to the display panel DP, the carrier film CAF may be removed. In other words, the panel protection films PPF may remain on the display panel DP, and only the carrier film CAF may be removed.

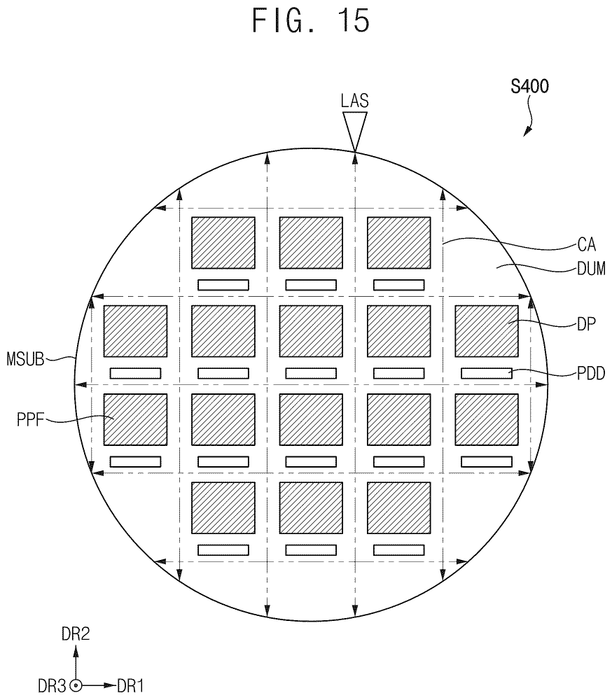

Referring to FIGS. 15, 16, and 17, the dummy area DUM may be removed by cutting the mother substrate MSUB (S400).

The mother substrate MSUB may be cut to form a plurality of substrates SUB. The mother substrate MSUB may be cut by irradiating a laser LAS. However, the present disclosure is not limited thereto, and the mother substrate MSUB may be cut by a physical processing method using a diamond wheel or dicing saw. The mother substrate MSUB may be cut along sides adjacent to the display panel DP and the pad portion PDD, respectively, and the other sides adjacent to the display panel DP and the pad portion PDD, respectively. Accordingly, only the cell area CA where the display panel DP and the pad part PDD are located may remain, and the dummy area DUM may be removed.

Referring to FIG. 18, a display cell DCE may be formed by removing the protection film PF (S500). For example, the display cell DCE may be formed by removing the panel protection films PPF.

After the mother substrate MSUB is cut, a subsequent process of polishing edges of the substrates SUB or connecting the pad portion PDD to the printed circuit board may be additionally performed. After the subsequent process, the panel protection films PPF overlapping the display panel DP may be removed. Accordingly, the display cell DCE including the substrate SUB, the display panel DP, and the pad portion PDD may be formed.

In one or more embodiments, after the protection film PF is removed, the polarization layer (e.g., the polarization layer POL of FIG. 3) may be formed on the display panel DP. The polarization layer POL may be formed after cutting the mother substrate MSUB. For example, after the panel protection films PPF are removed, the polarization layer may be formed on the encapsulation substrate. The panel protection films PPF may be removed after cutting the mother substrate MSUB. Accordingly, the display device DD, which is illustrated in FIG. 3, including the substrate SUB, the display panel DP, the pad portion PDD, and the polarization layer, may be formed.

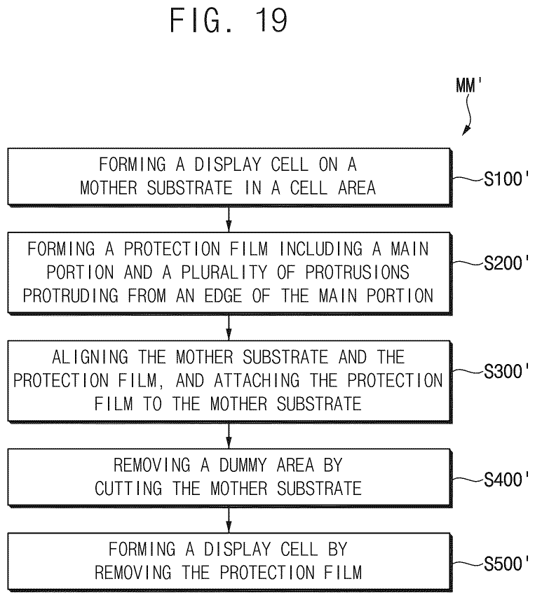

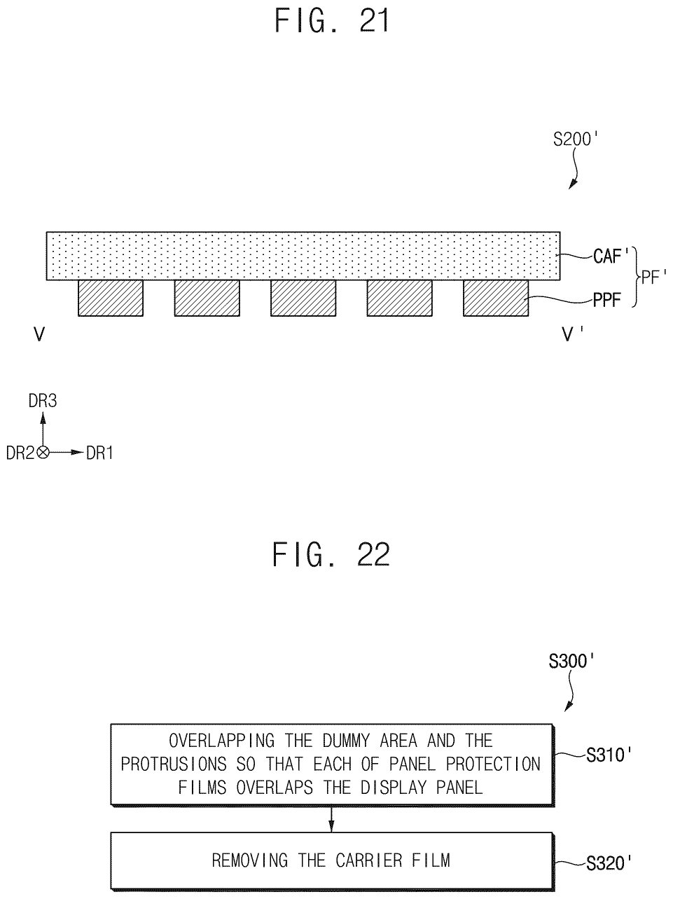

FIG. 19 is a flowchart illustrating a method of manufacturing a display device according to one or more other embodiments of the present disclosure. FIGS. 20, 21, 23, and 24 are views illustrating the method of manufacturing the display device of FIG. 19. FIG. 22 is a flowchart corresponding to the method of manufacturing the display device of FIG. 19.

Referring to FIG. 19, A method MM′ of manufacturing a display device according to one or more other embodiments of the present disclosure may include forming a display panel on a mother substrate in a cell area (S100′), forming a protection film including a main portion and a plurality of protrusions protruding from an edge of the main portion (S200′), aligning the mother substrate and the protection film, and attaching the protection film to the mother substrate (S300′), removing a dummy area by cutting the mother substrate (S400′), and forming a display cell by removing the protection film (S500′).

The forming a light-emitting element layer on a mother substrate (S100′) may be substantially the same as the forming a light-emitting element layer on a mother substrate (S100) described with reference to FIGS. 6 and 7. For example, the forming a display panel on a mother substrate (S100′) may be substantially the same as the forming a display panel on a mother substrate (S100) described with reference to FIGS. 6 and 7.

The removing the dummy area by cutting the mother substrate (S400′) may be substantially the same as the removing the dummy area by cutting the mother substrate (S400) described with reference to FIGS. 15, 16, and 17.

The forming a display cell by removing the protection film (S500′) may be substantially the same as the forming a display cell by removing the protection film (S500) described with reference to FIG. 18. Hereinafter, descriptions overlapping descriptions of the method MM of manufacturing the display device described with reference to FIGS. 6 to 18 will be omitted or simplified.

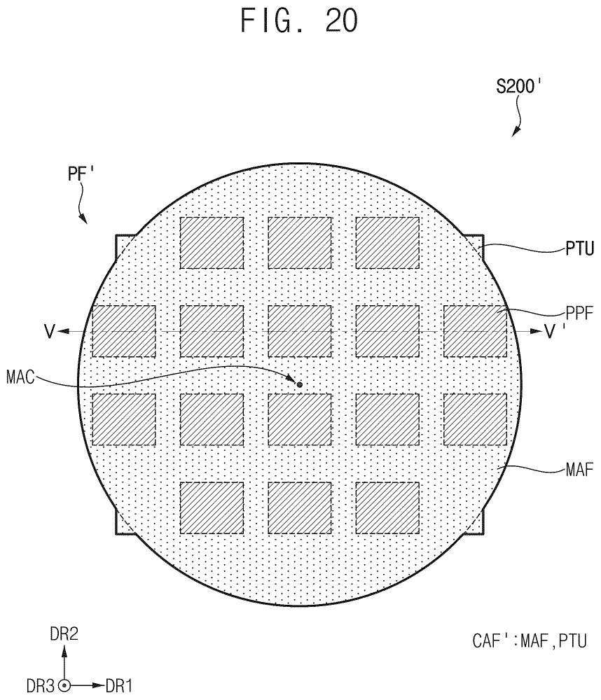

Referring to FIGS. 20 and 21, a protection film PF′ including a main portion MAF and a plurality of protrusions PTU protruding from an edge of the main portion MAF may be formed (S200′). The protection film PF′ may include a carrier film CAF′, and panel protection films PPF located on one surface of the carrier film CAF′.

The carrier film CAF′ may include the main portion MAF, and the protrusions PTU protruding from the edge of the main portion MAF. In one or more embodiments, the protrusions PTU may be point symmetrical to each other with respect to a center MAC of the main portion MAF. For example, four protrusions PTU, which are point symmetrical to each other with respect to the center MAC of the main portion MAF, may be formed at the edge of the main portion MAF. However, the present disclosure is not limited thereto, and two or six protrusions PTU, which are point symmetrical to each other with respect to the center MAC of the main portion MAF, may be formed at the edge of the main portion MAF.

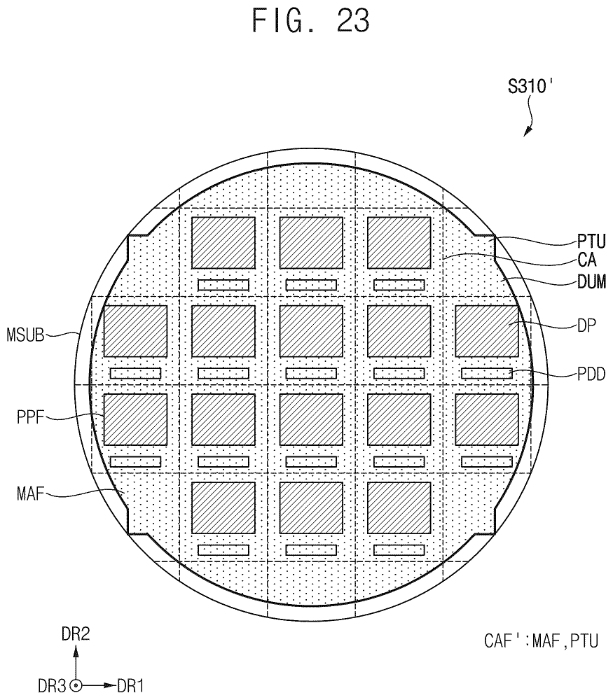

The main portion MAF may have a shape that corresponds to a shape of a mother substrate (e.g., a mother substrate MSUB of FIG. 23). For example, when the mother substrate has a circular planar shape, the main portion MAF may have a circular planar shape. For another example, when the mother substrate has an ellipse planar shape, the main portion MAF may have an ellipse planar shape.

In one or more embodiments, each of the protrusions PTU may have a substantially polygonal planar shape. For example, each of the protrusions PTU may have a substantially triangular planar shape or a rectangular planar shape. However, the present disclosure is not limited thereto.

The panel protection films PPF may be located on the one surface of the carrier film CAF′. The panel protection films PPF may be spaced apart from each other. Each of the panel protection films PPF may have a shape that corresponds to a shape of a display panel (e.g., a display panel DP of FIG. 23). For example, when the display panel has a rectangular planar shape, each of the panel protection films PPF may have a rectangular planar shape. In addition, each of the panel protection films PPF may have an area (or, size) corresponding to an area of the display panel.

A shape in which the panel protection films PPF are arranged on the carrier film CAF′ may correspond to a shape in which the display panels are arranged on the mother substrate. That is, a distance between the panel protection films PPF on the carrier film CAF′ may be the same as a distance between the display panels on the mother substrate. For example, when sixteen display panels are formed on the mother substrate, sixteen panel protection films PPF may be located on the carrier film CAF′.

Referring to FIGS. 22, 23, and 24, the aligning the mother substrate MSUB and the protection film PF′, and the attaching the protection film PF′ to the mother substrate MSUB (S300′) may include overlapping the dummy area DUM and the protrusions PTU so that each of the panel protection films PPF overlaps the display panel DP (S310′), and removing the carrier film CAF′ (S320′).

As illustrated in FIG. 23, the dummy area DUM and the protrusions PTU may overlap so that each of the panel protection films PPF overlaps the display panel DP (S310′).

The mother substrate MSUB and the protection film PF′ may be aligned with each other. For example, the dummy area DUM of the mother substrate MSUB and the protrusions PTU formed at the edge of the main portion MAF may be aligned with each other. In a process of forming the protrusions PTU at the edge of the main portion MAF of the carrier film CAF′, process dispersion may be reduced compared to a process of forming separate align marks on the carrier film CAF′. Accordingly, the alignment accuracy between the carrier film CAF′ and the mother substrate MSUB may be improved. When the mother substrate MSUB and the carrier film CAF′ are aligned so that the dummy area DUM and the protrusions PTU correspond, each of the panel protection films PPF may overlap the display panel DP in a plan view.

After aligning the mother substrate MSUB and the carrier film CAF′ so that the dummy area DUM and the protrusions PTU correspond, the protection film PF′ may be attached to the mother substrate MSUB. In this case, each of the panel protection films PPF may overlap the display panel DP, and the protrusions PTU may overlap the dummy area DUM. In other words, each of the panel protection films PPF may directly contact the display panel DP. In addition, the edge of the main portion MAF where the protrusions PTU are formed may directly contact the dummy area DUM of the mother substrate MSUB.

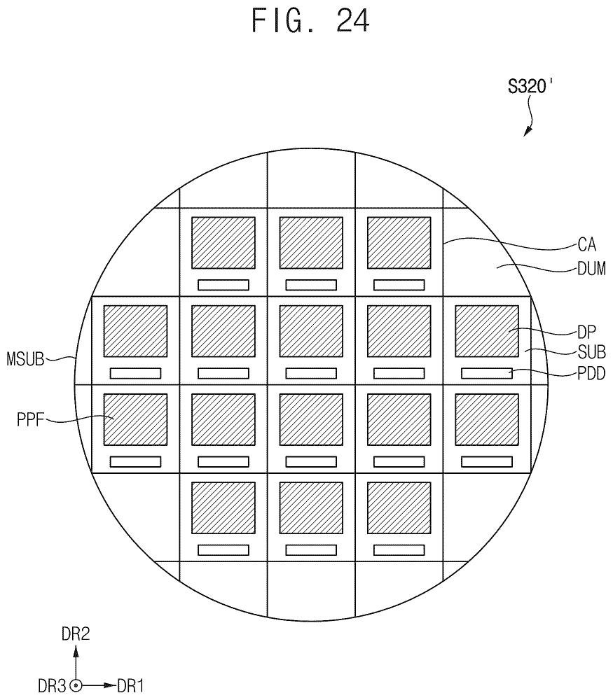

As illustrated in FIG. 24, the carrier film CAF′ may be removed (S320′).

After the carrier film CAF′ is aligned with the mother substrate MSUB and the panel protection films PPF are attached to the display panel DP, the carrier film CAF′ may be removed. In other words, the panel protection films PPF may remain on the display panel DP, and only the carrier film CAF′ may be removed.

After the carrier film CAF′ is removed, the dummy area DUM may be removed by cutting the mother substrate MSUB. After the mother substrate MSUB is cut, the panel protection films PPF overlapping the display panel DP may be removed. Accordingly, the display cell (e.g., the display cell DCE of FIG. 18) including the substrate SUB, the display panel DP, and the pad portion PDD may be formed. In one or more embodiments, after the protection film PF′ is removed, the polarization layer (e.g., the polarization layer POL of FIG. 3) may be formed on the display panel DP. For example, after the panel protection films PPF are removed, the polarization layer may be formed on the display panel DP. Accordingly, the display device DD, which is illustrated in FIG. 3, including the substrate SUB, the display panel DP, the pad portion PDD, and the polarization layer, may be formed.

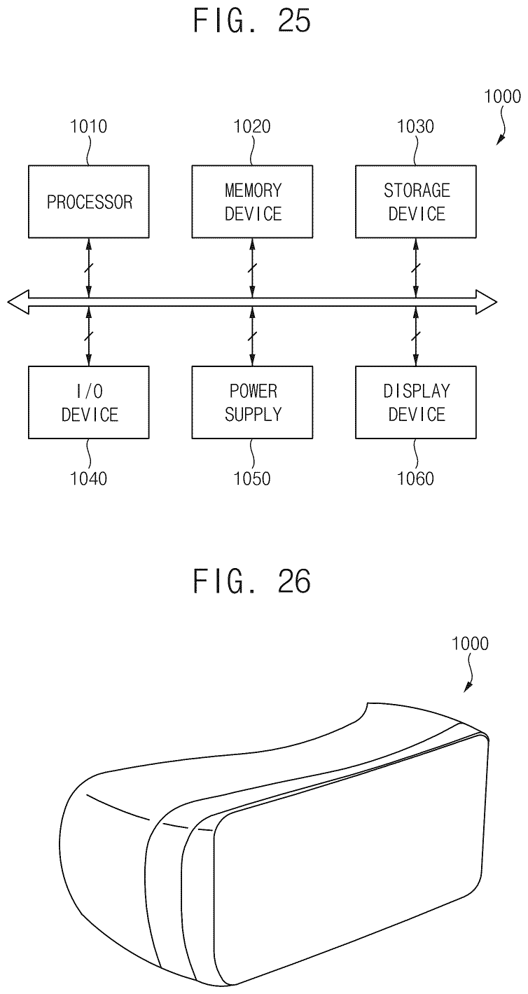

FIG. 25 is a block diagram illustrating an electronic device according to one or more other embodiments of the present disclosure. FIG. 26 is a view illustrating an example in which the electronic device of FIG. 25 is implemented as a head mounted display device.

Referring to FIGS. 25 and 26, an electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (“USB”) device, other systems, and the like.

In an embodiment, as illustrated in FIG. 26, the electronic device 1000 may be implemented as a head mounted display (“HMD”) device. However, the electronic device 1000 is not limited thereto. For example, the electronic device 1000 may be implemented as a smart pad, a smart watch, a tablet PC, a car navigation system, a computer monitor, a laptop, a smart phone, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The present disclosure may be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although embodiments have been described with reference to the figures, those skilled in the art will readily appreciate that many variations and modifications may be made therein without departing from the spirit and scope of the present disclosure as defined in the appended claims, with functional equivalents thereof to be included therein.

What is claimed is:

1. A method of manufacturing a display device, the method comprising:
forming a display panel above a mother substrate comprising a cell area, and a dummy area surrounding the cell area, such that the display panel overlaps the cell area;
forming cutouts by removing a portion of an edge of a protection film having a shape corresponding to a shape of the mother substrate;
aligning the mother substrate and the protection film so that the dummy area corresponds to the cutouts;
attaching the protection film to the mother substrate;
removing the dummy area by cutting the mother substrate; and
forming a display cell.

2. The method of claim 1, wherein the protection film comprises:
a carrier film having the cutouts at an edge of the carrier film; and
panel protection films on the carrier film and spaced apart from each other.

3. The method of claim 2, wherein the attaching the protection film to the mother substrate comprises:
overlapping the dummy area and the cutouts so that one of the panel protection films overlaps the display panel; and
removing the carrier film.

4. The method of claim 3, further comprising removing the panel protection films.

5. The method of claim 1, wherein the cutouts are respectively defined by a first cutting line extending in a first direction, and a second cutting line extending in a second direction crossing the first direction.

6. The method of claim 5, wherein the first cutting line is substantially perpendicular to the second cutting line.

7. The method of claim 1, wherein the cutouts are point symmetrical with respect to a center of the protection film.

8. The method of claim 1, further comprising forming a polarization layer above the display panel.

9. The method of claim 1, wherein the forming the display panel comprises:
forming a light-emitting element layer above the mother substrate in the cell area; and
forming an encapsulation layer above the light-emitting element layer.

10. The method of claim 9, wherein the forming the display panel further comprises:
forming a lens layer comprising micro lenses above the encapsulation layer; and
forming an encapsulation substrate above the lens layer.

11. The method of claim 1, wherein the mother substrate comprises a silicon wafer.

12. A method of manufacturing a display device, the method comprising:
forming a display panel above a mother substrate comprising a cell area and a dummy area surrounding the cell area, such that the display panel overlaps the cell area;
forming a protection film comprising a main portion having a shape corresponding to a shape of the mother substrate, and protrusions protruding from an edge of the main portion;
aligning the mother substrate and the protection film so that the dummy area corresponds to the protrusions;
attaching the protection film to the mother substrate;
removing the dummy area by cutting the mother substrate; and
forming a display cell.

13. The method of claim 12, wherein the protection film comprises:
a carrier film comprising the main portion and the protrusions; and
panel protection films on the carrier film and spaced apart from each other.

14. The method of claim 13, wherein the attaching the protection film to the mother substrate comprises:
overlapping the dummy area and the protrusions so that one of the panel protection films overlaps the display panel; and
removing the carrier film.

15. The method of claim 14, further comprising removing the panel protection films.

16. The method of claim 12, wherein the protrusions have a polygonal planar shape.

17. The method of claim 12, wherein the protrusions are point symmetrical with respect to a center of the main portion.

18. The method of claim 12, wherein the forming the display panel comprises:
forming a light-emitting element layer above the mother substrate in the cell area;
forming an encapsulation layer above the light-emitting element layer;
forming a lens layer comprising micro lenses above the encapsulation layer; and
forming an encapsulation substrate above the lens layer.

19. The method of claim 12, wherein the mother substrate comprises a silicon wafer.

20. An electronic device comprising:
a display device manufactured according to the method of claim 1; and
a power supply configured to provide power to the display device.
